(19) United States
(12) Patent Application Publication
(10) Pub. No.: US 2026/0255108 A1
(43) Pub. Date: Aug. 27, 2026

(54) Microelectromechanical Systems (MEMS) Transducers for High Sound Pressure Level (SPL) Measurements

(71) Applicant: Shure Acquisition Holdings, Inc., Niles, IL (US)

(72) Inventor: Jeffrey Peter Segota, Chicago, IL (US)

(21) Appl. No.: 19/548,149

(22) Filed: Feb. 24, 2026

Related U.S. Application Data
(60) Provisional application No. 63/762,466, filed on Feb. 24, 2025.

(51) Int. Cl. H04R 19/04; H04R 1/04; H04R 1/28; H04R 29/00

(52) U.S. Cl. CPC H04R 19/04; H04R 1/04; H04R 1/2807; H04R 29/004; H04R 2201/003

(57) ABSTRACT

Aspects of the disclosure relate to microelectromechanical systems (MEMS) devices for microphone applications. In particular, various examples herein describe techniques for limiting a diaphragm displacement of MEMS transducers to enable high sound pressure level (SPL) measurements. A reduced diaphragm displacement may be achieved by the use of an acoustic network, comprising an attenuator cavity, that may function to reduced an incident pressure on the diaphragm. The reduced diaphragm displacement may increase a maximum SPL handling capability of a MEMS transducer.

### CROSS-REFERENCE TO RELATED APPLICATION

This application claims the benefit of U.S. Provisional Patent Application No. 63/762,466, filed on Feb. 24, 2025, which is fully incorporated herein by reference.

### TECHNICAL FIELD

Aspects of the disclosure generally relate to microelectromechanical systems (MEMS) transducers, and more specifically relate to MEMS transducers for sound pressure measurements and/or microphone applications.

### BACKGROUND

Multiple microphone types, employing different technologies, are commercially available. Microphone types include, for example, dynamic microphones, condenser microphones, ribbon microphones, and microelectromechanical systems (MEMS) microphones. MEMS microphones offer many advantages over other microphone technologies. For example, MEMS microphones have a small footprint, a low cost, low power consumption, and allow easy integration with electronic components in a compact package. However, one significant disadvantage of MEMS microphones is that a maximum sound pressure that can be measured without significant distortion is lower than that associated with other audio measurement technologies.

A common MEMS transducer technology involves the use a diaphragm whose deformation and/or vibration may be electrically sensed. For example, a diaphragm of the MEMS transducer may be configured to deform/vibrate based on an input pressure or sound. Deformation or vibration of the diaphragm may be measured using different techniques. In one example, deformation or vibration of the diaphragm may be sensed as a change in capacitance of a capacitor comprising the diaphragm and a backplate in proximity to the diaphragm.

### SUMMARY

The following summary presents a simplified summary of certain features. The summary is not an extensive overview and is not intended to identify key or critical elements.

Various examples herein describe MEMS microphone systems for microphone/sound pressure measurement applications. An example MEMS microphone system may comprise a MEMS microphone (e.g., comprising a capacitive MEMS transducer with a diaphragm and a backplate) and an attenuator lid mounted on substrate. The MEMS microphone and the attenuator lid may be mounted on a same side/surface of the substrate or on opposite sides/surfaces of the substrate. The attenuator lid and the substrate may define an attenuator cavity. Opening(s) in a packaging of the MEMS microphone (e.g., on a lid or a base of the MEMS microphone) and/or the substrate may be used to connect a cavity of the MEMS microphone (e.g., a front cavity or a back cavity) to the attenuator cavity. The openings, in combination with the attenuator cavity, may function to reduce the sound pressure incident on the diaphragm. The reduced sound pressure may extend a maximum sound pressure level (SPL) that may be measured by the MEMS microphone without distortion.

These and other features and advantages are described in greater detail below.

### BRIEF DESCRIPTION OF THE DRAWINGS

The present disclosure is illustrated by way of example and not limited in the accompanying figures in which like reference numerals indicate similar elements and in which:

FIG. 1A shows a cross-section of an example MEMS microphone,

FIG. 1B shows a cross-section of an example MEMS microphone,

FIG. 1C shows a simplified lumped element model of a MEMS device,

FIG. 2 shows an example lumped element model that illustrates attenuation of a pressure wave as incident on a MEMS device,

FIG. 3A shows a cross-section of an example MEMS device with high SPL handling capability,

FIG. 3B shows an example lumped element model of a MEMS device,

FIG. 3C shows a comparison between frequency responses of different MEMS devices,

FIG. 4A shows a cross-section of an example MEMS device with high SPL handling capability,

FIG. 4B shows an example lumped element model of a MEMS device,

FIG. 4C shows a comparison between frequency responses of different MEMS devices,

FIG. 5A shows a cross-section of an example MEMS device with high SPL handling capability,

FIG. 5B shows an example lumped element model of a MEMS device, and

FIG. 6 shows a cross-section of an example MEMS device with high SPL handling capability,

FIG. 7 shows a cross-section of an example MEMS device with high SPL handling capability,

FIG. 8 shows a cross-section of an example MEMS device utilizing a stand-alone MEMS transducer, and

FIG. 9 shows an example method for assembling a MEMS device with high SPL handling capability.

### DETAILED DESCRIPTION

In the following description of various illustrative embodiments, reference is made to the accompanying drawings, which form a part hereof, and in which is shown, by way of illustration, various embodiments in which aspects of the disclosure may be practiced. It is to be understood that other embodiments may be utilized, and structural and functional modifications may be made, without departing from the scope of the present disclosure. It is noted that various connections between elements are discussed in the following description. It is noted that these connections are general and, unless specified otherwise, may be direct or indirect, wired or wireless, and that the specification is not intended to be limiting in this respect.

A typical MEMS transducer architecture, for pressure and/or sound pressure measurements, comprises a diaphragm which deforms in response to incident pressure. When applied for sound pressure measurements and/or microphone applications, the deformation may correspond to vibrations/oscillations of the diaphragm in response to an incident acoustic pressure wave. In a capacitive MEMS transducer, the vibrations/oscillations of the diaphragm may be measured as a change in capacitance of a capacitor comprising the diaphragm and a fixed backplate. Use of MEMS transducers for pressure wave sensing and/or microphone applications provide multiple advantages over conventional approaches. For example, MEMS transducers provide advantages such as reduced size and compatibility with conventional printed circuit board (PCB) manufacturing processes (e.g., such as reflow soldering) when compared to dynamic microphones, condenser microphones, or ribbon microphones. However, MEMS transducers may be at a disadvantage in relation to at least some audio performance parameters.

MEMS transducers for sound pressure measurements provide a signal output that corresponds to an input sound pressure level (SPL). SPL may correspond to change in pressure (e.g., a deviation from ambient/atmospheric pressure) caused by an acoustic wave. MEMS transducers typically suffer from reduced sound pressure level (SPL) handling capability. High SPLs may cause larger deformation/displacement of a diaphragm of a capacitive MEMS transducer. The non-linear nature of the deformation of the diaphragm may cause a signal output to have a high total harmonic distortion (THD) at high SPLs. Large deformation of the diaphragm may also result in clipping of a signal as measured by a read-out circuit (e.g., an application-specific integrated circuit (ASIC) configured to process the signal). An additional factor that may limit the maximum SPL performance is that the diaphragm may contact the backplate when exposed to high incident pressures. A parameter that may be used to quantify MEMS transducer performance is the acoustic overload point (AOP). AOP may be defined as an SPL required to produce 10% THD at 1 KHz audio frequency. A higher AOP may reflect a better (e.g., higher) SPL handling capability.

Various examples herein describe microphone devices and systems targeting a high pressure/SPL handling capability. High pressure performance in a microphone may be facilitated by the use of an acoustic network built around a pressure-measuring MEMS transducer (e.g., a capacitive MEMS transducer). The acoustic network may comprise an attenuator cavity configured to attenuate the acoustic pressure that the MEMS transducer is exposed to. Attenuation of the acoustic pressure may reduce deformation of the diaphragm. Reduced diaphragm deformation may enable linear operation over a higher pressure range and improve SPL performance.

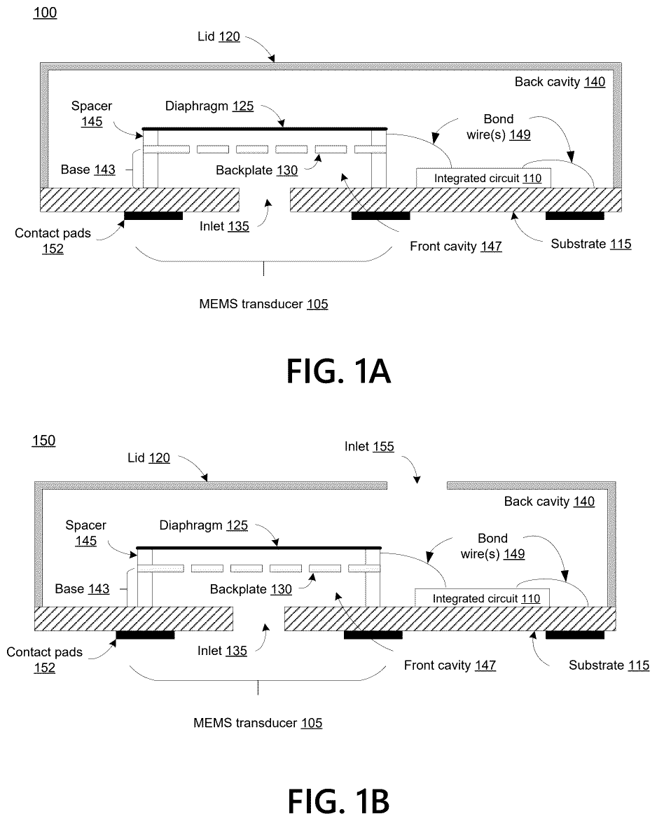

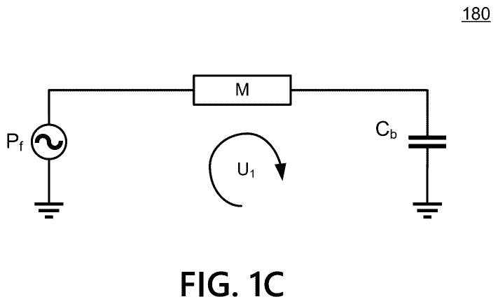

FIG. 1A shows a cross-section of an example MEMS microphone 100. The MEMS microphone 100 may correspond to/comprise a capacitive MEMS transducer for sound pressure measurements and/or microphone applications. The MEMS microphone 100 may comprise a MEMS transducer 105, an integrated circuit/application-specific integrated circuit (ASIC) 110, a substrate 115, and a lid 120. The MEMS microphone 100 may correspond to a bottom-port MEMS device.

The MEMS transducer 105 may correspond to a capacitive MEMS transducer comprising a backplate 130 and a moveable (e.g., deformable) diaphragm 125. The backplate 130 may be fixed and/or rigid within the MEMS transducer 105. The backplate 130 and the diaphragm 125 may be positioned near to, and spaced apart from, each other. The backplate 130 and the diaphragm 125 may be conductive, and/or may include electrodes (e.g., in the form of conductive metallic layers), that enable the backplate 130 and the diaphragm 125 to together function as a capacitor. The backplate 130 may comprise perforations (e.g., vent holes) that allow the diaphragm 125 to be exposed to sound pressure and/or to mitigate damping of motion (e.g., vibration) of the diaphragm 125. In response to an incident sound pressure wave, the diaphragm 125 may oscillate/vibrate about an equilibrium position (e.g., in a direction orthogonal/perpendicular to a surface of the diaphragm 125).

The MEMS transducer 105 may additionally comprise a base 143 and a spacer 145. The backplate 130 and the diaphragm 125 may be mounted on the base 143 and may be separated from each other by the spacer 145. The spacer 145 may function as an electrically insulating layer between the backplate 130 and the diaphragm 125. In an example, the backplate 130 and the base 143 may correspond to a monolithic structure. The MEMS transducer 105 may be mounted on an inlet 135 located in the substrate 115. The inlet 135 may function as an acoustic port that transfers incident sound pressure/audio to the MEMS transducer 105. The MEMS microphone 100 may correspond to a bottom-port MEMS microphone based on the inlet 135 being located on the substrate 115.

The MEMS transducer 105, as mounted on the substrate 115, may have a different arrangement of the diaphragm 125 and the backplate 130. While FIG. 1A shows the backplate 130 being near (e.g., directly above, adjacent to) the inlet 135, in other examples, the diaphragm 125 may be near (e.g., directly above, adjacent to) the inlet 135 (e.g., with the backplate 130 being located over the diaphragm 125 and away from the inlet 135). In other words, the diaphragm 125 of the MEMS transducer 105, as mounted on the substrate 115, may be below the backplate 130.

The integrated circuit 110 may be configured to measure a capacitance and/or a change in capacitance of the MEMS transducer 105 and generate an output signal corresponding to the capacitance and/or the change in capacitance. The output signal may correspond to pressure/SPL that the MEMS transducer 105 is exposed to via the inlet 135.

The integrated circuit 110 may be mounted on the substrate 115 and may be electrically connected to the diaphragm 125 and the backplate 130 of the MEMS transducer 105. Electrical connection(s) between the integrated circuit 110 and the MEMS transducer 105 may be via one or more bond wire(s) 149. Additionally, or alternatively, the connection(s) between the integrated circuit 110 and the MEMS transducer 105 may be via conductive tracks on the substrate 115 (e.g., which may be a printed circuit board (PCB)).

The one or more bond wire(s) 149, conductive tracks, and/or vias may be used to connect one or more components of the MEMS microphone 100 (e.g., the MEMS transducer 105 and/or the integrated circuit 110) to conductive contact pads 152 located on a lower surface of the substrate 115. The contact pads 152 may be used to provide input power to and receive output signals as generated by the integrated circuit 110 and/or the MEMS transducer 105. The contact pads 152 may be used to electrically connect (e.g., solder, surface mount) the MEMS microphone 100 to a PCB and/or any other external circuit configured to operate the MEMS microphone 100.

The MEMS transducer 105 and the integrated circuit 110 may be packaged on the substrate 115 using a lid 120. The packaged MEMS microphone 100 may comprise a front cavity 147 and a back cavity 140 separated by the diaphragm 125. The back cavity 140 may correspond to a cavity, of the MEMS microphone 100, located on the side of the diaphragm 125 that is away from the inlet 135. With respect to the MEMS microphone 100, a region defined (e.g., encapsulated, bounded) by the lid 120 and the substrate 115, and surrounding the MEMS transducer 105 may correspond to the back cavity 140. The front cavity 147 may correspond to a cavity, of the MEMS microphone 100, located on the side of the diaphragm 125 that is adjacent (e.g., closer) to the inlet 135. For example, a region defined by (e.g., between) the inlet 135 and the diaphragm 125 may correspond to the front cavity 147.

The diaphragm 125, the backplate 130, and/or the base 143 may be fabricated from silicon (e.g., single crystal silicon, polysilicon, doped polysilicon, amorphous silicon), any other semiconductor material (e.g., GaAs, InP, Si/Ge, and/or SiC), a metal, and/or any other material. For example, the backplate 130 may be fabricated from single crystal silicon, and the diaphragm 125 may be fabricated from doped polysilicon. The spacer 145 may comprise any insulating material (e.g., silicon dioxide, silicon nitride, etc.). In an example, the MEMS transducer 105 may be fabricated using a semiconductor die (e.g., comprising silicon or any other semiconductor material) with one or more layers of material (e.g., polysilicon) that are deposited to form the diaphragm 125 and/or the backplate 130.

The lid 120 may be fabricated using metal, ceramic, polymer, and/or any other material. The lid 120 may be coupled/affixed to the substrate 115 using an adhesive, or using any other bonding technique. The substrate 115 may correspond to a PCB, and/or may comprise plastic, ceramic, and/or laminate material. In an example, the substrate 115 may comprise conductive lines/tracks, pins, and/or tabs that may be used to electrically connect (e.g., using soldering, surface mounting, or connections using bond wires) the MEMS microphone 100 to one or more other components of a microphone system (not shown). The one or more bond wire(s) 149, contact pads 152, and conductive components in the substrate 115 may be fabricated from any conductive material (e.g., gold, copper, silver, aluminum, and/or any other metal or metal alloy).

The MEMS transducer 105 and the integrated circuit 110, as shown in FIG. 1A, may correspond to separate structures. For example, the MEMS transducer 105 and the integrated circuit 110 may be fabricated on separate dies and mounted on the substrate 115. In other examples, the MEMS transducer 105 and the integrated circuit 110 may be fabricated on a same die.

While the MEMS microphone 100 shows the inlet 135 through the substrate 115, in other examples, an inlet may instead be located on the lid 120. In some examples, inlets may be located on both the substrate 115 and the lid 120 (e.g., with one inlet on the substrate 115 and another inlet on the lid 120).

FIG. 1B shows a cross-section of an example MEMS microphone 150. The MEMS microphone 150 may be substantially similar to the MEMS microphone 100, with the exception that the MEMS microphone 150 may comprise an additional inlet 155 located on the lid 120 (e.g., in addition to the inlet 135). The provision of two inlets (e.g., inlet 135 and inlet 155) may cause the MEMS microphone 150 to have direction-dependent characteristics. For example, the MEMS microphone 150 may provide a higher sensitivity to incident sound waves that are received from a direction that is perpendicular to the substrate 115 than to incident sound waves that are received from a direction that is parallel to the substrate 115. Accordingly, the MEMS microphone 150 may correspond to a directional MEMS microphone with a pick-up pattern exhibiting higher sensitivities in directions substantially perpendicular to the substrate 115. Like-numbered components of the MEMS microphone 150 and the MEMS microphone 100 are similar, or substantially similar.

In at least some embodiments, inlets in MEMS microphones 100, 150 (e.g., inlets 135, 155) may be covered by acoustic resistances to achieve desired audio characteristics and/or for protecting the MEMS transducer 105. The acoustic resistances may comprise one or more of a fabric, a foam, a sintered material, etc. The acoustic resistance may comprise a hole-array (e.g., micro-machined or laser-drilled hole array) or a mesh.

Operation in a linear range of an acoustic MEMS device (e.g., the MEMS microphone 100 and/or the MEMS transducer 105) may be described using a lumped element model. The lumped element model may quantify a relation between an applied pressure P and a resultant volume velocity U₁. The volume velocity U₁ may be used to determine a diaphragm displacement of a MEMS transducer. The diaphragm displacement may result in a change in capacitance of a capacitor comprising the diaphragm and a backplate. The change in capacitance may be reflected as a change in a parameter (e.g., voltage and/or current) associated with a circuit (e.g., comprising the capacitor). In this manner, the lumped element model may be used to relate incident pressure to an electrical output generated by the MEMS device.

FIG. 1C shows a simplified lumped element model 180 of a MEMS device (e.g., the MEMS microphone 100). The lumped element model 180 may be represented by a circuit comprising a pressure wave source P_{f} (e.g., via the inlet 135), a component M representing a MEMS transducer (e.g., the MEMS transducer 105), and the acoustic compliance C_{b} of a back cavity (e.g., the back cavity 140). U₁ may be the volume velocity of air, within the MEMS device, as caused by pressure wave source P_{f}. The component M may account for the performance of the acoustic elements of the MEMS transducer and electromechanical coupling (e.g., between electrical and mechanical domains of the MEMS device) that may influence a response of the MEMS device. The lumped element model 180 ignores a compliance of a front cavity of the MEMS device (e.g., the front cavity 147), which may be small in comparison to the back cavity.

As previously described, a major cause of THD and limitation on the AOP may be the non-linear deformation of the diaphragm, especially at the high SPLs. A MEMS transducer system design that attenuates a sound pressure level incident on the MEMS transducer will result in reduced diaphragm displacement and may produce more favorable THD/AOP performance.

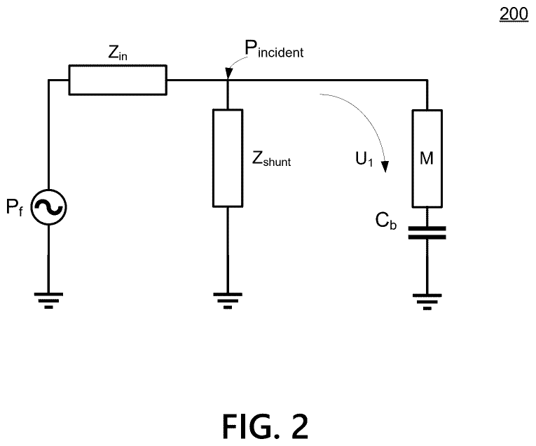

FIG. 2 shows an example lumped element model 200 that illustrates attenuation of a pressure wave in a MEMS device. The lumped element model 200 may be represented by a circuit comprising a pressure wave source P_{f}, an input impedance Zᵢₙ (e.g., a resistance covering an inlet of the MEMS device), an impedance of a shunt element Zₛₕᵤₙₜ functioning as an attenuator, a component M representing a MEMS transducer (e.g., the MEMS transducer 105) in the MEMS device, and the acoustic compliance C_{b} of a back cavity (e.g., the back cavity 140). For Zₛₕᵤₙₜ<<M, incident pressure wave P_{incident} at the MEMS transducer may be given as:

$${P}_{i n cident} \approx ( \frac{{Z}_{shunt}}{{Z}_{shunt} + {Z}_{i n}} ) {P}_{f} \qquad Equation ( 1 )$$

As is clear from FIG. 2 and Equation (1), P_{incident} at the MEMS transducer is reduced in relation to a MEMS device that does not comprise a shunt element Zₛₕᵤₙₜ. The reduced pressure wave P_{incident} may cause lower diaphragm displacement in comparison to devices (e.g., such as the devices shown in FIGS. 1A-1C) that do not comprise an attenuating system.

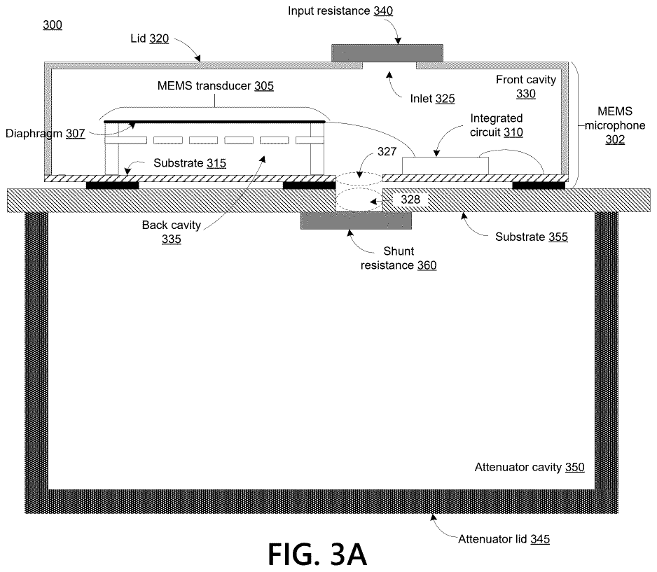

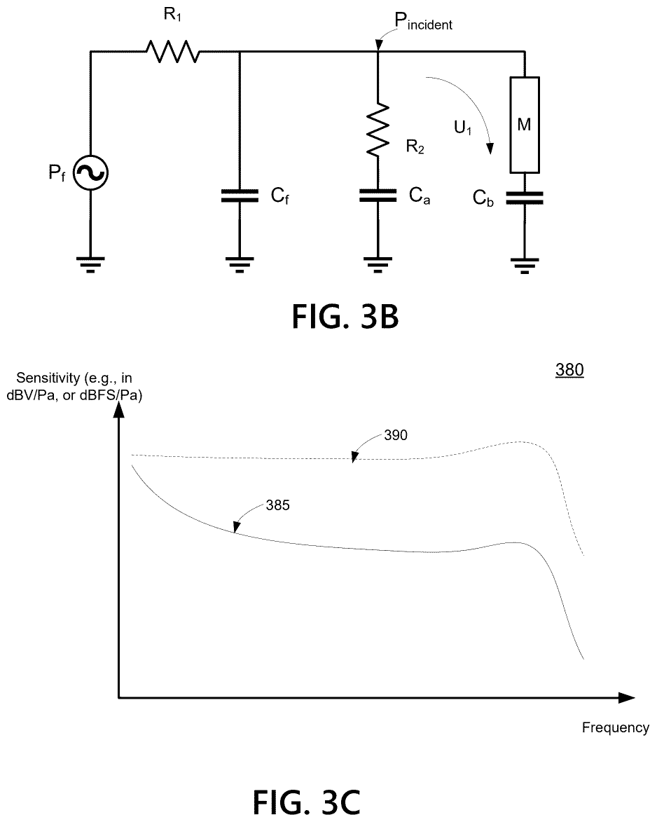

FIG. 3A shows a cross-section of an example MEMS device 300 with high SPL handling capability. The MEMS device 300 may correspond to/comprise a capacitive MEMS transducer for sound pressure measurements and/or microphone applications. The high SPL handling capability may be provided by an acoustic network, built around the MEMS transducer, that may reduce an incident pressure (e.g., an amplitude of an incident pressure wave) on the MEMS transducer.

The MEMS device 300 may comprise a MEMS microphone 302 and an attenuator lid 345 coupled to (e.g., positioned on, affixed to) a substrate 355. The MEMS microphone 302 and the attenuator lid 345 may be coupled/affixed to different surfaces/sides of the substrate 355. For example, the MEMS microphone 302 may be coupled to (e.g., mounted on, attached to) a top surface of the substrate 355 and the attenuator lid 345 may be coupled to (e.g., attached to) a bottom surface of the substrate 355. The MEMS microphone 302 and/or the attenuator lid 345 may be affixed to the substrate 355 using soldering, adhesive, and/or any other bonding technique.

The MEMS microphone 302 may be similar to, or substantially to the same as, the MEMS microphones 100, 150. For example, the MEMS microphone 302 may comprise a MEMS transducer 305, a corresponding integrated circuit 310, a substrate 315, and a lid 320, which may be similar to, or substantially the same as, the MEMS transducer 105, the integrated circuit 110, the substrate 115, and the lid 120, respectively. The MEMS microphone 302 may comprise an inlet 325 located on the lid 320. An incident pressure wave/audio may enter the MEMS microphone 302 via the inlet 325.

The substrate 355 may correspond to a PCB, and/or may comprise metal, plastic, ceramic, and/or laminate material. In an example, the substrate 355 may comprise conductive lines/tracks, pins, and/or tabs that may be used to electrically connect (e.g., using soldering, surface mounting, or connections using bond wires) the MEMS microphone 302 (e.g., the MEMS transducer 305 and/or the integrated circuit 310) and/or the MEMS device 300 to one or more other components of a microphone system (not shown). The attenuator lid 345 may be fabricated using metal, ceramic, polymer, and/or any other material.

The MEMS microphone 320 may comprise a front cavity 330 and a back cavity 335 separated by a diaphragm 307 of the MEMS transducer 305. The front cavity 330 may correspond to a cavity, of the MEMS microphone 302, located on the side of the diaphragm 305 that is adjacent (e.g., closer) to the inlet 325. For example, a region defined (e.g., encapsulated, bounded) by the lid 320 and the substrate 315, and surrounding the MEMS transducer 305 may correspond to the front cavity 330. The back cavity 335 may correspond to a cavity, of the MEMS microphone 302, located on the side of the diaphragm 307 that is away from the inlet 325. With respect to the MEMS microphone 302, a region defined (e.g., encapsulated, bounded) by the substrate 315 and the MEMS transducer 305 (e.g., by the diaphragm 307) may correspond to the back cavity 335. A region defined (e.g., encapsulated, bounded) by the attenuator lid 345 and the substrate 355 may correspond to an attenuator cavity 350.

The front cavity 330 and the attenuator cavity 350 may be connected via an opening 327 in the substrate 315 and an opening 328 in the substrate 355. A connection (or a linkage/coupling) between two cavities, as described herein, may comprise that air, sound wave, and/or sound pressure from a first cavity may enter a second cavity via one or more openings (e.g., in a pathway between the first cavity and the second cavity). The pathway between the front cavity 330 and the attenuator cavity 350, via the openings 327, 328, may enable reduction of an incident pressure on the diaphragm 307. Reduced incident pressure may reduce incident volume velocity at the diaphragm 307 and reduce the resultant diaphragm displacement.

One or more of the openings of the MEMS device 300 (e.g., inlet 325, openings 327, 328) may be covered by acoustic resistances to achieve desired audio characteristics and/or for protecting the MEMS transducer 105. For example, the inlet 325 may be covered by an input resistance 340 and/or the opening 328 may be covered by a shunt resistance 360. The input resistance 340 and/or the shunt resistance 360 may comprise one or more of a fabric, a foam, a sintered material, a hole-array (e.g., micro-machined or laser-drilled hole array), a mesh, etc.

FIG. 3B shows an example lumped element model 370 of the MEMS device 300. The lumped element model 370 may be represented by a circuit comprising a pressure wave P_{f} (e.g., via the inlet 325), acoustic resistance R₁ of the input resistance 340, an acoustic compliance C_{f} of the front cavity 330, acoustic resistance R₂ of the shunt resistance 360, an acoustic compliance Cₐ of the attenuator cavity 350, a component M representing the MEMS transducer 305, and an acoustic compliance C_{b} of the back cavity 335.

As described with respect to FIG. 2, presence of a shunt element (e.g., in the form of a large acoustic compliance Cₐ of the attenuator cavity 350) would result in an attenuated pressure wave P_{incident} at the MEMS transducer.

FIG. 3C shows a comparison 380 between a frequency response 385 of the MEMS device 300 and a frequency response 390 of a MEMS device without an attenuating system (e.g., the MEMS microphone 100). The frequency response 380 may be based on the lumped element model 370 and the frequency response 390 may be based on the lumped element model 180 as shown in FIG. 1C.

The frequency responses 380, 390 show sensitivities as a function of a frequency of the incident pressure wave P_{f}. The sensitivity may be measured as a ratio of an amplitude (e.g., a voltage amplitude for an analog system or decibels relative to full scale (dBFS) for a digital system) of a generated output signal, as caused by a change in capacitance of a MEMS transducer (e.g., the MEMS transducer 305, or the MEMS transducer 105), and an amplitude of the incident pressure wave P_{f}.

As shown in FIG. 3C, the frequency response 380 shows a lower sensitivity than the frequency response 390. The reduced sensitivity exhibits the functionality of the attenuator cavity 350, of the MEMS device 300, in reducing the pressure incident on the MEMS transducer, thereby enabling favorable THD/AOP performance. The frequency response 380 shows a rise in sensitivity at low frequencies, which may result in output signal distortion. The low frequency rise in sensitivity may be caused by the attenuator cavity 350 being of finite size.

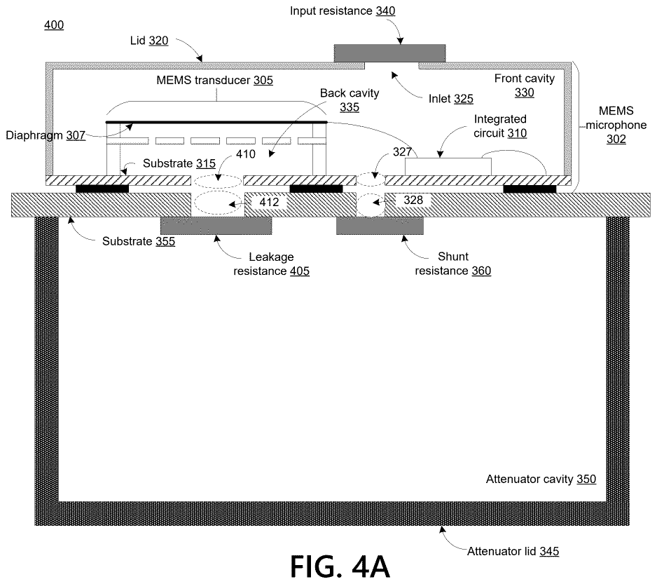

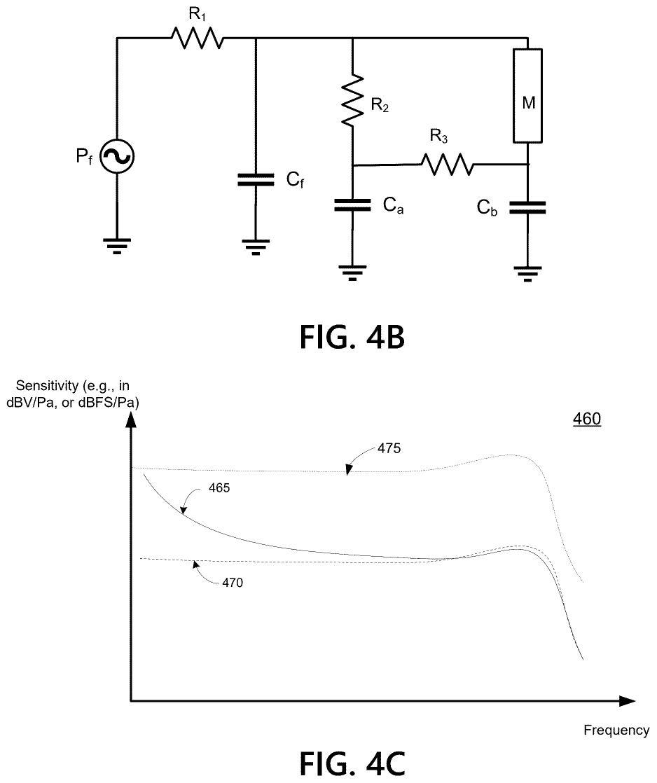

FIG. 4A shows a cross-section of an example MEMS device 400 with high SPL handling capability. The example MEMS device 400 may correspond to/comprise a capacitive MEMS transducer for sound pressure measurements and/or microphone applications. The high SPL handling capability may be provided by an acoustic network, built around the MEMS transducer, that may reduce an incident pressure (e.g., an amplitude of an incident pressure wave) on the MEMS transducer. Like-numbered components in the MEMS devices 300, 400 may be similar, or substantially the same, in construction and/or operation.

In contrast to the MEMS device 300, in the MEMS device 400, the back cavity 335 of the MEMS microphone 302 may also be connected to the attenuator cavity 350. For example, the back cavity 335 may be connected to the attenuator cavity 350 via opening 410 in the substrate 315 and opening 412 in the substrate 355. As further described, this additional pathway between the MEMS microphone 302 and the attenuator cavity 350 may counteract the low frequency rise in sensitivity as shown in FIG. 3C. The opening 412 (and/or the opening 410) that connects the back cavity 355 to the attenuator cavity 350 may be covered by a leakage resistance 405 (e.g., a fabric, a foam, a sintered material, a hole-array, a mesh, etc.).

FIG. 4B shows an example lumped element model 450 of the MEMS device 400. The lumped element model 450 may be substantially similar to the lumped element model 370 with the exception of an acoustic resistance R₃, of the leakage resistance 405, connecting the acoustic compliance Cₐ of the attenuator cavity 350 and the acoustic compliance C_{b} of the back cavity 335. The acoustic resistance R₃ between the acoustic compliance Cₐ of the attenuator cavity 350 and the acoustic compliance C_{b} of the back cavity 335 may model the connection between the attenuator cavity 350 and back cavity 335 (via openings 410, 412).

FIG. 4C shows a comparison 460 between frequency responses of different MEMS devices. Frequency response 465 may correspond to a frequency response of the MEMS device 300 based on the lumped element model 370 (e.g., as also shown in FIG. 3C). Frequency response 470 may correspond to a frequency response of the MEMS device 400 based on the lumped element model 450. As shown in FIG. 4C, the low frequency rise as observed in the frequency response 465 is not present in the frequency response 470. The flat frequency response 465 at low frequencies illustrates that the connection between the attenuator cavity 350 and back cavity 335 (e.g., as modeled by the acoustic resistance R₃) functions to equalize the potential low frequency rise in the frequency response of the MEMS device 400. For reference, FIG. 4C also shows a frequency response 475 of a MEMS device without an attenuating system (e.g., the MEMS microphone 100). For example, the frequency response 475 may be based on the lumped element model 180 as shown in FIG. 1C.

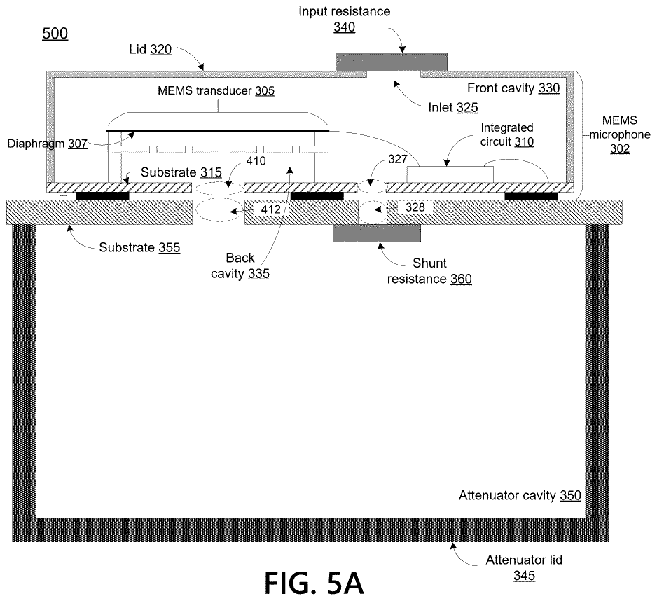

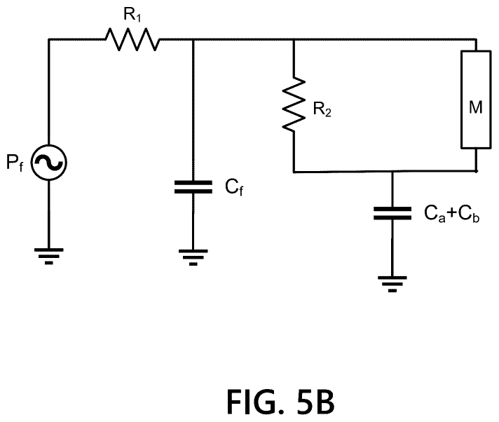

FIG. 5A shows a cross-section of an example MEMS device 500 with high SPL handling capability. The example MEMS device 500 may correspond to/comprise a capacitive MEMS transducer for sound pressure measurements and/or microphone applications. The high SPL handling capability may be provided by an acoustic network, built around the MEMS transducer, that may reduce an incident pressure (e.g., an amplitude of an incident pressure wave) on the MEMS transducer. Like-numbered components in the MEMS devices 300, 400, 500 may be similar, or substantially the same, in construction and/or operation.

In contrast to the MEMS device 400 of FIG. 4A, in the MEMS device 500, the back cavity 335 of the MEMS microphone 302 may be connected to the attenuator cavity 350 without the use of a leakage resistance (e.g., the leakage resistance 405 at opening 412 as shown in FIG. 4A). In this case, the back cavity 335 and the attenuator cavity 350 may effectively function as a single cavity for attenuating an incident pressure wave.

FIG. 5B shows an example lumped element model 550 of the MEMS device 500. The lumped element model 550 may be substantially similar to the lumped element model 450 with the exception that the acoustic resistance R₃ is zero (e.g., because of the absence of the leakage resistance 405 as shown in FIG. 4A).

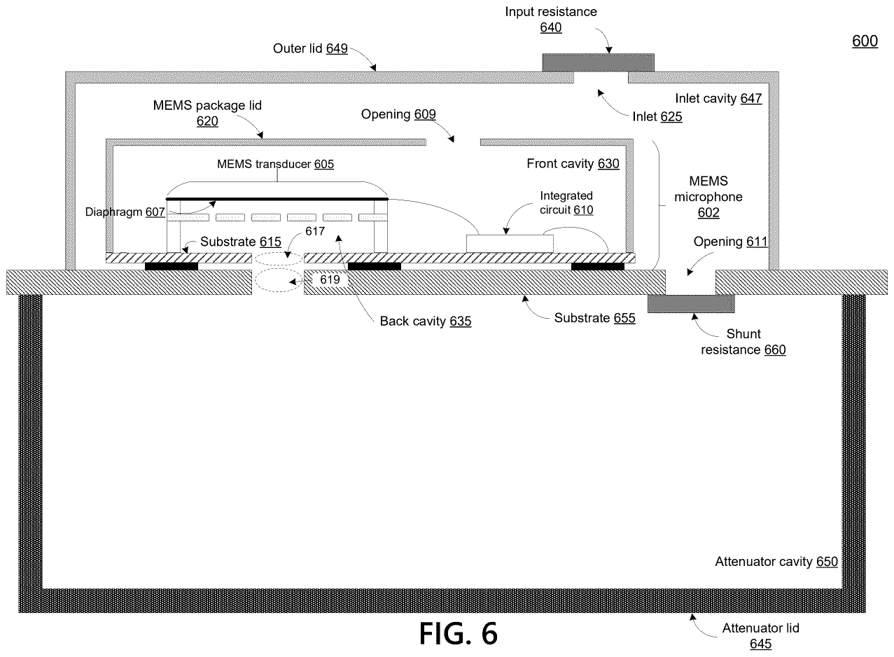

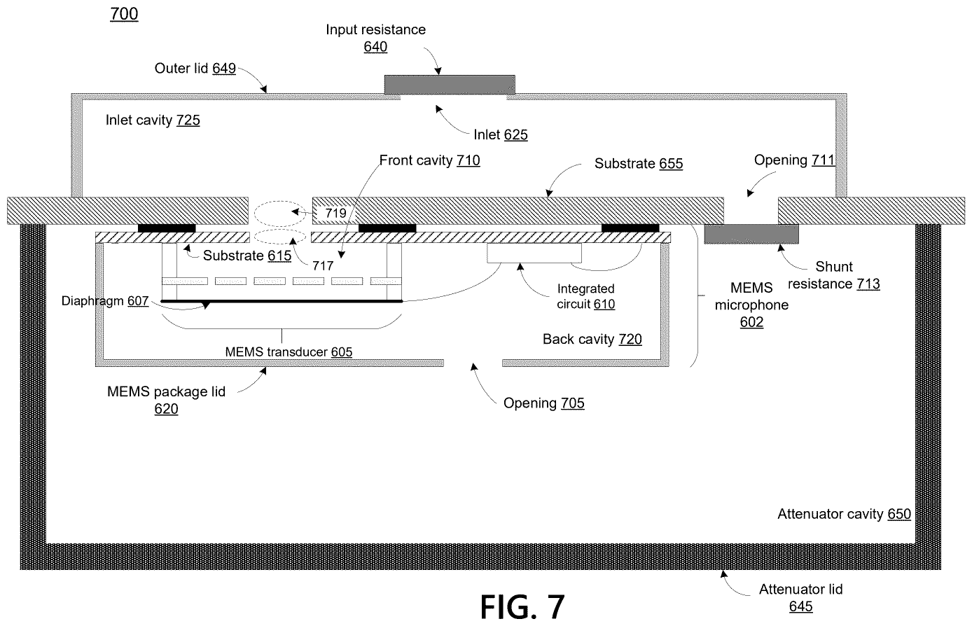

The MEMS devices 300, 400, 500 use a MEMS microphone 302 in conjunction with attenuator lid 345 to achieve the desired SPL handling and frequency response characteristics. To provide the connection between the front cavity 330 of the MEMS microphone 302 and the attenuator cavity 350, an opening (e.g., the opening 327) in the substrate 315 of the MEMS microphone 302 needs to be provided/fabricated. However, commercially available MEMS microphones generally only have an opening on a lid of the package and/or on the substrate of the package underneath the MEMS transducer (e.g., inlets 135, 155 as shown in FIGS. 1A and 1). Accordingly, assembly of the MEMS devices 300, 400, 500 from commercially available MEMS microphones would require additional fabrication steps to create another opening in the substrate (e.g., to connect a front cavity to an attenuator cavity). FIGS. 6 and 7 show example MEMS devices that may avoid the necessity of additional fabrication steps and enable use of commercially available MEMS microphones without any modification.

FIG. 6 shows a cross-section of an example MEMS device 600 with high SPL handling capability. The MEMS device 600 may correspond to/comprise a capacitive MEMS transducer for sound pressure measurements and/or microphone applications. The high SPL handling capability may be provided by an acoustic network, built around the MEMS transducer, that may reduce an incident pressure (e.g., an amplitude of an incident pressure wave) on the MEMS transducer.

The MEMS device 600 may comprise a MEMS microphone 602 and an attenuator lid 645 coupled to (e.g., positioned on, affixed to) a substrate 655. The MEMS microphone 602 and the attenuator lid 645 may be coupled to (e.g., positioned on, affixed to) different surfaces/sides of the substrate 655. For example, the MEMS microphone 602 may be coupled to (e.g., mounted on, attached to) a top surface of the substrate 655 and the attenuator lid 645 may be coupled to (e.g., attached to) a bottom surface of the substrate 655. The MEMS microphone 602 and/or the attenuator lid 645 may be affixed to the substrate 655 using soldering, adhesive, and/or any other bonding technique.

The MEMS microphone 602 may be similar to, or substantially the same as, the MEMS microphones 100, 150. For example, the MEMS microphone 602 may comprise a MEMS transducer 605, a corresponding integrated circuit 610, a substrate 615, and a MEMS package lid 620, which may be similar to, or substantially the same as, the MEMS transducer 105, the integrated circuit 110, the substrate 115, and the lid 120, respectively. The MEMS microphone 602 may comprise an opening 609 located on the MEMS package lid 620. The MEMS microphone 602 may comprise an additional opening 617 located in the substrate 615 underneath the MEMS transducer 605.

The MEMS microphone 602 may be encapsulated using an outer lid 649 that is coupled to (e.g., positioned on) the substrate 655. For example, the outer lid 649 may be affixed to the substrate (e.g., using soldering, adhesive, and/or any other bonding technique). A region defined (e.g., encapsulated, bounded) by the outer lid 649 and the substrate 655, and surrounding the MEMS microphone 602 (e.g., MEMS package lid 620) may correspond to an inlet cavity 647 of the MEMS device 600. The outer lid 649 may comprise an inlet 625. An incident pressure wave/audio may enter the MEMS microphone 602 via the inlet 625 and the opening 609.

The MEMS microphone 602 may comprise a front cavity 630 and a back cavity 635 separated by the diaphragm 607. The front cavity 630 may be a cavity, of the MEMS microphone 602, located on the side of the diaphragm 607 that is adjacent (e.g., closer) to the opening 609 and closer to the inlet 625. For example, a region defined (e.g., encapsulated, bounded) by the MEMS package lid 620 and the substrate 615, and surrounding the MEMS transducer 605 may correspond to the front cavity 630 of the MEMS microphone 602. The back cavity 635 may be a cavity, of the MEMS microphone 602, located on the side of the diaphragm 607 that is away from the opening 609 and/or the inlet 625. For example, a region defined (e.g., encapsulated, bounded) by the substrate 615 and the MEMS transducer 605 (e.g., the diaphragm 607) may correspond to the back cavity 635. A region defined (e.g., encapsulated, bounded) by the attenuator lid 645 and the substrate 655 may correspond to an attenuator cavity 650 of the MEMS device 600.

The inlet cavity 647 and the attenuator cavity 650 may be connected via an opening 611 in the substrate 655. This pathway between the inlet cavity 647 and the attenuator cavity 650 may enable reduction of an incident pressure on the diaphragm 607. Reduce incident pressure may reduce incident volume velocity at the diaphragm 607 and reduce the resultant diaphragm displacement.

The back cavity 635 may be connected to the attenuator cavity 650 via the opening 617 in the substrate 615 and an opening 619 in the substrate 655. As described with reference to FIG. 4A, this additional pathway to the attenuator cavity 650 may counteract any low frequency rise in sensitivity of the MEMS device 600.

One or more of the inlets/openings of the MEMS device 600 (e.g., the inlet 625, the openings 609, 611, 617, 619) may be covered by acoustic resistances to achieve desired audio characteristics and/or for protecting the MEMS transducer 605. For example, the inlet 625 may be covered by an input resistance 640 and/or the opening 611 in the substrate 655 (e.g., connecting the inlet cavity 647 to the attenuator cavity 650) may be covered by a shunt resistance 660. The input resistance 640 and/or the shunt resistance 660 may comprise one or more of a fabric, a foam, a sintered material, a hole-array (e.g., micro-machined or laser-drilled hole array), a mesh, etc.

The substrate 655 may correspond to a PCB, and/or may comprise metal, plastic, ceramic, and/or laminate material. In an example, the substrate 655 may comprise conductive lines/tracks, pins, and/or tabs that may be used to electrically connect (e.g., using soldering, surface mounting, or connections using bond wires) the MEMS microphone 602 and/or the MEMS device 600 to one or more other components of a microphone system (not shown). The attenuator lid 645 and/or the outer lid 649 may be fabricated using metal, ceramic, polymer, and/or any other material.

In the MEMS device 600, the coupling between the MEMS microphone 602 and the substrate 655 is in a manner such that the substrate 615 of the MEMS microphone 602 is coupled to (e.g., positioned on, attached to) the substrate 655. In other examples, the MEMS microphone 602 may be coupled to the substrate in an inverted manner. For example, the coupling between the MEMS microphone 602 and the substrate 655 may be such that the MEMS package lid 620 of the MEMS microphone 602 is coupled to (e.g., positioned on, attached to) the substrate 655. In this case, an opening in the MEMS package lid 620 (e.g., the opening 609) may connect the attenuator cavity 650 to a back cavity of the MEMS microphone 602 (e.g., via the opening 619).

FIG. 7 shows a cross-section of an example MEMS device 700 with high SPL handling capability. The MEMS device 700 may correspond to/comprise a capacitive MEMS transducer for sound pressure measurements and/or microphone applications. The high SPL handling capability may be provided by an acoustic network, built around the MEMS transducer, that may reduce an incident pressure (e.g., an amplitude of an incident pressure wave) on the MEMS transducer. Like-numbered components in the MEMS devices 600, 700 may be similar, or substantially the same, in construction and/or operation.

Similar to the MEMS device 600, the MEMS device 700 may comprise the MEMS microphone 602 and the attenuator lid 645 coupled to (e.g., positioned on, affixed to) the substrate 655. However, in contrast to the MEMS device 600, the MEMS device 700 may comprise the MEMS microphone 602 and the attenuator lid 645 coupled to (e.g., positioned on, affixed to) a same surface/side of the substrate 655. As shown in FIG. 7, the arrangement may be such that the attenuator lid 645 and the substrate 655 may encapsulate the MEMS microphone 602 within the attenuator cavity 650. In this arrangement, the attenuator cavity 650 may correspond to a region defined (e.g., encapsulated, bounded) by the attenuator lid 645 and the substrate 655, and surrounding the MEMS microphone 602. The MEMS microphone 602 may comprise an opening 705 located on the MEMS package lid 620.

The MEMS device 700 may comprise an outer lid 649 that is coupled to (e.g., positioned on) the substrate 655. For example, the outer lid 649 may be affixed to the substrate (e.g., using soldering, adhesive, and/or any other bonding technique). The outer lid 649 may be coupled/affixed to a different surface of the substrate 655 than the surface to which the MEMS microphone 602 and the attenuator lid 645 are coupled. For example, the outer lid 649 may be mounted on a top surface of the substrate 655, and the attenuator lid 645 and the MEMS microphone 602 may be attached to a bottom surface of the substrate 655.

A region defined (e.g., encapsulated, bounded) by the outer lid 655 and the substrate 655 may correspond to an inlet cavity 725 of the MEMS device 700. Similar to the MEMS device 600, the outer lid 649 may comprise the inlet 625. An incident pressure wave may enter the MEMS device 700 via the inlet 625.

The MEMS microphone 602, in the MEMS device 700, may comprise a front cavity 710 and a back cavity 720 separated by the diaphragm 607. The front cavity 710 may be a cavity, of the MEMS microphone 602, located on the side of the diaphragm 607 that is closer to the inlet 625. For example, a region defined (e.g., encapsulated, bounded) by the substrate 615 and the MEMS transducer 605 (e.g., the diaphragm 607) may correspond to the front cavity 710. The back cavity 720 may be a cavity, of the MEMS microphone 602, located on the side of the diaphragm 607 that is away from the inlet 625. For example, a region defined (e.g., encapsulated, bounded) by the MEMS package lid 620 and the substrate 615, and surrounding the MEMS transducer 605 may correspond to the back cavity 720 of the MEMS microphone 602.

The inlet cavity 725 and the attenuator cavity 650 may be connected via an opening 711 in the substrate 655. This pathway between the inlet cavity 725 and the attenuator cavity 650 may enable reduction of an incident pressure on the diaphragm 607. Reduced incident pressure may reduce incident volume velocity at the diaphragm 607 and reduce the resultant diaphragm displacement.

Further, the back cavity 720 may be connected to the attenuator cavity 650 via the opening 705 in the MEMS package lid 620. The front cavity 710 may be connected to the inlet cavity 725 via an opening 717 in the substrate 615 and an opening 719 in the substrate 655.

One or more of the inlets/openings of the MEMS device 700 (e.g., the inlet 625, the openings 705, 711, 717, 719) may be covered by acoustic resistances to achieve desired audio characteristics and/or for protecting the MEMS transducer 605. For example, the inlet 625 may be covered by an input resistance 640 and/or the opening 711 in the substrate 655 (e.g., connecting the inlet cavity 725 to the attenuator cavity 650) may be covered by a shunt resistance 713. The input resistance 640 and/or the shunt resistance 713 may comprise one or more of a fabric, a foam, a sintered material, a hole-array (e.g., micro-machined or laser-drilled hole array), a mesh, etc.

In the MEMS device 700, the coupling between the MEMS microphone 602 and the substrate 655 is in a manner such that the substrate 615 of the MEMS microphone 602 is coupled to (e.g., positioned on, attached to) the substrate 655. In other examples, the MEMS microphone 602 may be coupled to the substrate in an inverted manner. For example, the coupling between the MEMS microphone 602 and the substrate 655 may be such that the MEMS package lid 620 of the MEMS microphone 602 is coupled to (e.g., positioned on, attached to) the substrate 655. In this case, an opening in the MEMS package lid 620 (e.g., the opening 705) may connect the inlet cavity 725 to a front cavity of the MEMS microphone 602 (e.g., via the opening 719).

The MEMS devices 300, 400, 500, 600, 700 utilize packaged transducers (e.g., MEMS microphones 302, 602) for their construction. A MEMS device may employ standalone MEMS transducers to achieve similar high SPL handling capabilities.

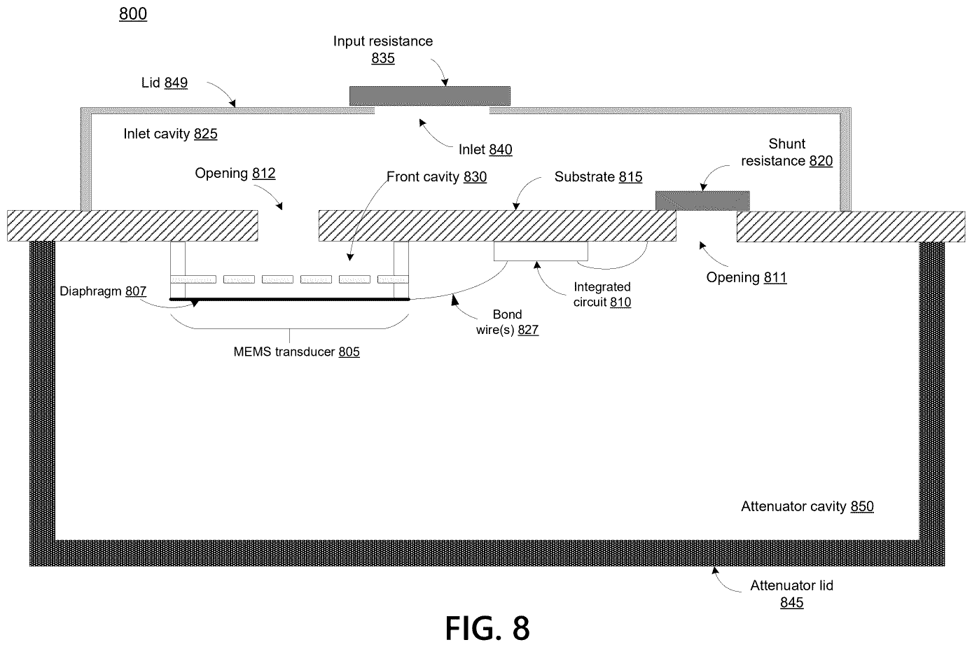

FIG. 8 shows a cross-section of an example MEMS device 800 utilizing a stand-alone MEMS transducer. The MEMS device 800 may correspond to/comprise a capacitive MEMS transducer for sound pressure measurements and/or microphone applications. The high SPL handling capability may be provided by an acoustic network, built around the MEMS transducer, that may reduce an incident pressure (e.g., an amplitude of an incident pressure wave) on the MEMS transducer.

The MEMS device 800 may comprise a stand-alone MEMS transducer 805 and an attenuator lid 845 coupled to (e.g., positioned on, affixed to) a substrate 815. The MEMS transducer 805 and the attenuator lid 845 may be coupled to (e.g., positioned on, affixed to) the same side/surface of the substrate 815. As shown in FIG. 8, the arrangement may be such that the attenuator lid 845 and the substrate 815 may encapsulate the MEMS transducer 805 within an attenuator cavity 850. In other arrangements, the MEMS transducer 805 and the attenuator lid 845 may be coupled/affixed to opposite sides of the substrate 815. For example, the MEMS transducer 805 may be positioned on a top surface of the substrate 815 and the attenuator lid 845 may be positioned on a bottom surface of the substrate 815. The MEMS transducer 805 and/or the attenuator lid 845 may be coupled/affixed to the substrate 815 using soldering, adhesive, and/or any other bonding technique. The attenuator lid 845 may be fabricated using metal, ceramic, polymer, and/or any other material.

The MEMS transducer 805 may be similar to, or substantially the same as, the MEMS transducer 105 as shown in FIGS. 1A and 1B. For example, the MEMS transducer 805 may comprise a diaphragm (e.g., diaphragm 807), a backplate, a base, and/or a spacer that are similar, or substantially similar, to the diaphragm 125, the backplate 130, the base 143, and/or the spacer 145 as shown in FIGS. 1A and 1B.

An integrated circuit 810 may be configured to measure a capacitance and/or a change in capacitance of the MEMS transducer 805 and generate an output signal corresponding to the capacitance and/or the change in capacitance. The output signal may correspond to pressure/SPL that the MEMS transducer 805 is exposed to. Electrical connection(s) between the integrated circuit 810 and the MEMS transducer 805 may be via one or more bond wire(s) 827. Additionally, or alternatively, the connection(s) between the integrated circuit 810 and the MEMS transducer 805 may be via conductive tracks on the substrate 815 (e.g., which may be a PCB). The integrated circuit 810 may be affixed to the substrate 815 using soldering, adhesive, and/or any other bonding technique. The integrated circuit 810 may be positioned on a same side (e.g., surface) of the substrate as the MEMS transducer 805.

The substrate 815 may correspond to a PCB, and/or may comprise metal, plastic, ceramic, and/or laminate material. In an example, the substrate 815 may comprise conductive lines/tracks, pins, and/or tabs that may be used to electrically connect (e.g., using soldering, surface mounting, or connections using bond wires) the MEMS transducer 805, the integrated circuit 810, and/or the MEMS device 800 to one or more other components of a microphone system (not shown).

The MEMS device 800 may comprise a lid 849 that is coupled/affixed to the substrate 815 (e.g., using an adhesive or any other bonding technique). The lid 849 may be coupled/affixed to a different surface of the substrate 815 than the surface to which the MEMS transducer 805 and the attenuator lid 845 are coupled. For example, the lid 849 may be coupled to (e.g., mounted on, attached to) a top surface of the substrate 815, and the attenuator lid 845 and the MEMS transducer 805 may be coupled to (e.g., attached to) a bottom surface of the substrate 815. In an example arrangement wherein the MEMS transducer 805 and the attenuator lid 845 are coupled to different surfaces of the substrate 815, the lid 849 may be positioned to encapsulate the MEMS transducer 805.

A region defined (e.g., encapsulated, bounded) by the lid 849 and the substrate 815 may correspond to an inlet cavity 825 of the MEMS device 800. Similar to MEMS devices 600, 700, the lid 849 may comprise an inlet 840. An incident pressure wave may enter the MEMS device 800 via the inlet 840.

With respect to the MEMS device 800, a region defined by (e.g., between) the substrate 815 and the MEMS transducer 805 (e.g., the diaphragm 807) may correspond to a front cavity 830. For example, the front cavity 710 may be a cavity located on the side of a diaphragm 807 (e.g., of the MEMS transducer 805) that is closer to the inlet 840. The front cavity 830 may be connected to the inlet cavity 825 via an opening 812 in the substrate 815. The opening 812 may enable the pressure wave to impact the diaphragm 805 and cause diaphragm displacement.

The inlet cavity 825 and the attenuator cavity 850 may be connected via an opening 811 in the substrate 815. This pathway between the inlet cavity 825 and the attenuator cavity 850 may enable reduction of an incident pressure on the diaphragm 807. Reduced incident pressure may reduce incident volume velocity at the diaphragm 807 and reduce the resultant diaphragm displacement.

One or more of the inlets/openings of the MEMS device 800 (e.g., the inlet 840, the openings 811, 812) may be covered by acoustic resistances to achieve desired audio characteristics and/or for protecting the MEMS transducer 805. For example, the inlet 840 may be covered by an input resistance 835 and/or the opening 811 may be covered by a shunt resistance 820. The input resistance 835 and/or the shunt resistance 820 may comprise one or more of a fabric, a foam, a sintered material, a hole-array (e.g., micro-machined or laser-drilled hole array), a mesh, etc.

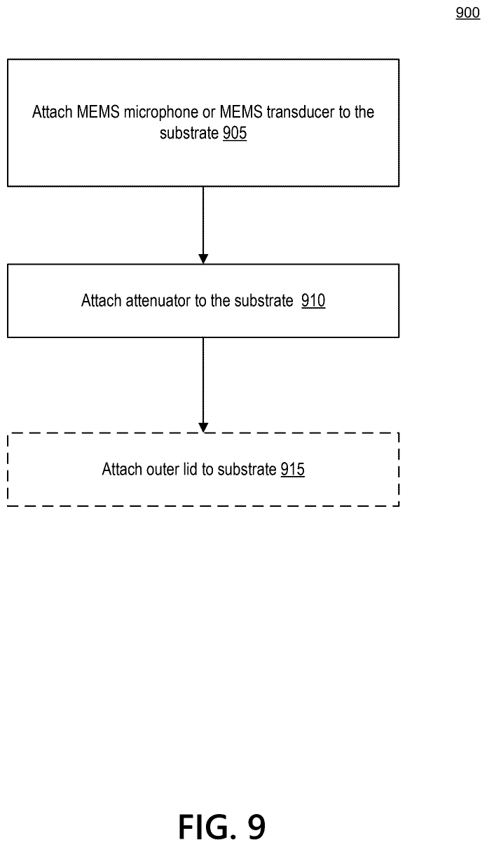

FIG. 9 shows an example method 900 for assembling a MEMS device with high SPL handling capability. The example method 900 may be used to fabricate any of the MEMS devices described herein (e.g., MEMS devices 300, 400, 500, 600, 700).

At step 905, a MEMS microphone (e.g., the MEMS microphone 302, 602) may be positioned on (e.g., coupled to, attached to) a substrate (e.g., as described with respect to FIGS. 3A, 4A, 4D, 5A, 6 and 7). The MEMS microphone may comprise a MEMS transducer (e.g., a capacitive MEMS transducer) and an ASIC. Alternatively, a stand-alone MEMS transducer and an associated ASIC may be directly positioned on (e.g., coupled to, attached to) the substrate (e.g., as described with respect to FIG. 8). The substrate may comprise conductive lines/tracks, pins, and/or tabs that may be used to electrically connect (e.g., solder, surface mount, or connect using bond wires) the MEMS microphone, or the MEMS transducer and the ASIC to the substrate.

At step 910, an attenuator lid may be positioned on (e.g., coupled to, attached to) the substrate. The coupling/attachment between the attenuator lid and the substrate may be performed using an adhesive (e.g., an epoxy), soldering, or any other technique. The attenuator lid may be attached on a different surface (e.g., an opposite surface of the substrate) than the surface on which the MEMS microphone/MEMS transducer is attached. For example, the MEMS microphone (or MEMS transducer) may be attached to a top surface of the substrate, while the attenuator lid may be attached to bottom surface of the substrate. Alternatively, the attenuator lid may be attached to the same surface of the substrate on which the MEMS microphone or the MEMS transducer is attached (e.g., as shown in FIGS. 7 and 8). Openings in the substrate (and, if used, the MEMS microphone) may be fabricated such that an attenuator cavity (e.g., as encapsulated by the attenuator lid and the substrate) may be connected to a cavity associated with the MEMS microphone/MEMS transducer (e.g., a front cavity of the MEMS microphone, as shown in FIGS. 3A, 4A, 4D, 5A; and/or a back cavity of the MEMS microphone as shown in FIGS. 5A, 6, and 7).

At step 915, optionally, a lid may be positioned on (e.g., coupled to, attached to) the substrate. For example, the lid may be an outer lid positioned/attached over the MEMS microphone (e.g., as shown in FIG. 6). For devices that include the attenuator lid and the MEMS microphone/MEMS transducer on a same first surface of the substrate (e.g., as shown in FIGS. 7 and 8), the lid (e.g., the outer lid 649 in FIG. 7, the lid 849 in FIG. 8) may be positioned/attached on a second surface (e.g., different from the first surface) of the substrate. The outer lid may comprise an inlet providing a pathway, for an incident pressure wave, to a diaphragm of the MEMS transducer.

While various examples herein describe MEMS devices comprising capacitive MEMS transducers, in other examples, the MEMS devices may comprise/utilize any other type of transduction technology that may be used to measure diaphragm displacement/vibrations. For example, the techniques as described herein to improve an SPL handling capability may be applied to piezoelectric and/or piezoresistive diaphragm-based MEMS transducers (or any other diaphragm-based MEMS transducers). A piezoresistive diaphragm-based MEMS transducer, for example, may provide a measure of diaphragm displacement as a change in resistance of one or more piezoresistive strain gages attached to a surface of the diaphragm.

A microphone system may comprise multiple components. The microphone system may comprise a first substrate, a MEMS microphone, and an attenuator lid. The MEMS microphone may be coupled to a top surface of the first substrate. The MEMS microphone may comprise a MEMS transducer mounted on a second substrate and enclosed by a lid. The lid may comprise an audio inlet into a front cavity of the MEMS microphone. The attenuator lid may be coupled to a bottom surface of the first substrate. The attenuator lid and the first substrate may encapsulate an attenuator cavity. The front cavity of the MEMS microphone and the attenuator cavity may be connected via a first opening in the first substrate and a second opening in the second substrate. The microphone system may further comprise a second lid, coupled to the top surface of the first substrate. The second lid may comprise an audio inlet into an inlet cavity encapsulated by the second lid and the first substrate. The MEMS transducer may comprise a backplate, and a diaphragm separated from the backplate by a width. The front cavity may comprise a region, surrounding the MEMS transducer, encapsulated by the lid and the second substrate. The MEMS microphone may comprise a back cavity that is encapsulated by the second substrate and the MEMS transducer. The back cavity and the attenuator cavity may be connected via a third opening in the first substrate and a fourth opening in the second substrate. At least one of the audio inlet or the first opening may be covered by an acoustic resistance element. The MEMS microphone may further comprise an ASIC configured to measure a change in capacitance of the MEMS transducer. The first substrate comprises a PCB electrically connected to the MEMS microphone via one or more contact pads on the second substrate.

A microphone system may comprise multiple components. The microphone system may comprise a first substrate and a MEMS microphone coupled to a top surface of the first substrate. The MEMS microphone comprises a MEMS transducer mounted on a second substrate and enclosed by a first lid. The first lid may comprise a first opening into a front cavity of the MEMS microphone. The microphone system may additionally comprise a second lid, coupled to the top surface of the first substrate and enclosing the MEMS microphone. The second lid may comprise an audio inlet into an inlet cavity encapsulated by the second lid and the first substrate. microphone system may additionally comprise an attenuator lid coupled to a bottom surface of the first substrate. The attenuator lid and the first substrate may encapsulate an attenuator cavity. The inlet cavity and the attenuator cavity may be connected via a second opening in the first substrate. The MEMS transducer may comprise a backplate, and a diaphragm separated from the backplate by a width. The front cavity may comprise a region, surrounding the MEMS transducer, encapsulated by the lid and the second substrate. The MEMS microphone may comprise a back cavity that is encapsulated by the second substrate and the MEMS transducer. The back cavity and the attenuator cavity may be connected via a third opening in the first substrate and a fourth opening in the second substrate. At least one of the audio inlet, the first opening, or the second opening may be covered by an acoustic resistance element. The MEMS microphone may further comprise an ASIC configured to measure a change in capacitance of the MEMS transducer. The first substrate may comprise a printed circuit board (PCB) electrically connected to the MEMS microphone via one or more contact pads on the second substrate.

A microphone system may comprise multiple components. The microphone system may comprise a first substrate and a MEMS microphone coupled to a bottom surface of the first substrate. The MEMS microphone may comprise a MEMS transducer mounted on a second substrate and enclosed by a first lid. The microphone system may further comprise a second lid coupled to a top surface of the first substrate. The second lid may comprise an audio inlet into an inlet cavity encapsulated by the second lid and the first substrate. The inlet cavity may be connected to a first cavity of the MEMS microphone via a first opening in the first substrate. The microphone system may further comprise an attenuator lid coupled to a bottom surface of the first substrate and enclosing the MEMS microphone. The attenuator lid and the first substrate may encapsulate an attenuator cavity. The inlet cavity and the attenuator cavity may be connected via a second opening in the first substrate. The MEMS transducer may comprise a backplate and a diaphragm separated from the backplate by a width. The first cavity may comprise a region, surrounding the MEMS transducer, encapsulated by the first lid and the second substrate. The MEMS microphone may comprise a second cavity encapsulated by the second substrate and the MEMS transducer. The first cavity of the MEMS microphone may comprise a region encapsulated by the second substrate and the MEMS transducer. The MEMS microphone may comprise a second cavity. The second cavity may be a region, surrounding the MEMS transducer, encapsulated by the first lid and the second substrate. The second cavity of the MEMS microphone and the attenuator cavity are connected via a third opening in the first lid or the second substrate. At least one of the audio inlet, the first opening, or the second opening are covered by an acoustic resistance element. The MEMS microphone may further comprise an ASIC configured to measure a change in capacitance of the MEMS transducer. The first substrate may comprise a PCB electrically connected to the MEMS microphone via one or more contact pads on the second substrate.

A microphone system may comprise multiple components. The microphone system may comprise a substrate, a MEMS transducer coupled to a bottom surface of the substrate, and a lid coupled to atop surface of the substrate. The lid may comprise an audio inlet into an inlet cavity encapsulated by the lid and the substrate. The inlet cavity may be connected to a cavity of the MEMS transducer via a first opening in the substrate. The microphone system may further comprise an attenuator lid coupled to a bottom surface of the substrate and enclosing the MEMS transducer. The attenuator lid and the substrate may encapsulate an attenuator cavity. The inlet cavity and the attenuator cavity may be connected via a second opening in the substrate. The cavity of the MEMS transducer may comprise a region encapsulated by the substrate and the MEMS transducer. The MEMS transducer may comprise a backplate and a diaphragm separated from the backplate by a width. At least one of the audio inlet, the first opening, or the second opening may be covered by an acoustic resistance element. The microphone system may further comprise an ASIC configured to measure a change in capacitance of the MEMS transducer. The substrate may comprise a PCB electrically connected to the MEMS transducer via one or more contact pads on the substrate.

One or more aspects of the disclosure may be embodied in computer-usable data or computer-executable instructions, such as in one or more program modules, executed by one or more computers or other devices to perform the operations described herein. Generally, program modules include routines, programs, objects, components, data structures, and the like that perform particular tasks or implement particular abstract data types when executed by one or more processors in a computer or other data processing device. The computer-executable instructions may be stored as computer-readable instructions on a computer-readable medium such as a hard disk, optical disk, removable storage media, solid-state memory, RAM, and the like. The functionality of the program modules may be combined or distributed as desired in various embodiments. In addition, the functionality may be embodied in whole or in part in firmware or hardware equivalents, such as integrated circuits, application-specific integrated circuits (ASICs), field programmable gate arrays (FPGA), and the like. Particular data structures may be used to more effectively implement one or more aspects of the disclosure, and such data structures are contemplated to be within the scope of computer executable instructions and computer-usable data described herein.

Various aspects described herein may be embodied as a method, an apparatus, or as one or more computer-readable media storing computer-executable instructions. Accordingly, those aspects may take the form of an entirely hardware embodiment, an entirely software embodiment, an entirely firmware embodiment, or an embodiment combining software, hardware, and firmware aspects in any combination. In addition, various signals representing data or events as described herein may be transferred between a source and a destination in the form of light or electromagnetic waves traveling through signal-conducting media such as metal wires, optical fibers, or wireless transmission media (e.g., air or space). In general, the one or more computer-readable media may be and/or include one or more non-transitory computer-readable media.

Aspects of the disclosure have been described in terms of illustrative embodiments thereof. Numerous other embodiments, modifications, and variations within the scope and spirit of the appended claims will occur to persons of ordinary skill in the art from a review of this disclosure. For example, one or more of the steps depicted in the illustrative figures may be performed in other than the recited order, and one or more depicted steps may be optional in accordance with aspects of the disclosure.

1. A microphone system comprising:
a first substrate;
a microelectromechanical system (MEMS) microphone coupled to a top surface of the first substrate, wherein the MEMS microphone comprises a MEMS transducer mounted on a second substrate and enclosed by a lid, wherein the lid comprises an audio inlet into a front cavity of the MEMS microphone; and
an attenuator lid coupled to a bottom surface of the first substrate, wherein:
the attenuator lid and the first substrate encapsulate an attenuator cavity, and
the front cavity of the MEMS microphone and the attenuator cavity are connected via a first opening in the first substrate and a second opening in the second substrate.

2. The microphone system of claim 1, further comprising a second lid, coupled to the top surface of the first substrate, wherein the second lid comprises an audio inlet into an inlet cavity encapsulated by the second lid and the first substrate.

3. The microphone system of claim 1, wherein the MEMS transducer comprises: a backplate, and a diaphragm separated from the backplate by a width.

4. The microphone system of claim 1, wherein:
the front cavity comprises a region, surrounding the MEMS transducer, encapsulated by the lid and the second substrate, and
the MEMS microphone comprises a back cavity that is encapsulated by the second substrate and the MEMS transducer.

5. The microphone system of claim 4, wherein the back cavity and the attenuator cavity are connected via a third opening in the first substrate and a fourth opening in the second substrate.

6. The microphone system of claim 1, wherein at least one of the audio inlet or the first opening are covered by an acoustic resistance element.

7. The microphone system of claim 1, wherein the first substrate comprises a printed circuit board (PCB) electrically connected to the MEMS microphone via one or more contact pads on the second substrate.

8. A microphone system comprising:
a first substrate;
a microelectromechanical system (MEMS) microphone coupled to a bottom surface of the first substrate, wherein the MEMS microphone comprises a MEMS transducer mounted on a second substrate and enclosed by a first lid;
a second lid coupled to a top surface of the first substrate, wherein the second lid comprises an audio inlet into an inlet cavity encapsulated by the second lid and the first substrate, wherein the inlet cavity is connected to a first cavity of the MEMS microphone via a first opening in the first substrate; and
an attenuator lid coupled to a bottom surface of the first substrate and enclosing the MEMS microphone, wherein:
the attenuator lid and the first substrate encapsulate an attenuator cavity, and
the inlet cavity and the attenuator cavity are connected via a second opening in the first substrate.

9. The microphone system of claim 8, wherein the MEMS transducer comprises: a backplate and a diaphragm separated from the backplate by a width.

10. The microphone system of claim 8, wherein:
the first cavity comprises a region, surrounding the MEMS transducer, encapsulated by the first lid and the second substrate, and
the MEMS microphone comprises a second cavity encapsulated by the second substrate and the MEMS transducer.

11. The microphone system of claim 8, wherein the first cavity of the MEMS microphone comprises a region encapsulated by the second substrate and the MEMS transducer.

12. The microphone system of claim 8, wherein the MEMS microphone comprises a second cavity, wherein the second cavity is a region, surrounding the MEMS transducer, encapsulated by the first lid and the second substrate.

13. The microphone system of claim 8, wherein a second cavity of the MEMS microphone and the attenuator cavity are connected via a third opening in the first lid or the second substrate.

14. The microphone system of claim 8, wherein at least one of the audio inlet, the first opening, or the second opening are covered by an acoustic resistance element.

15. A microphone system comprising:
a substrate;
a microelectromechanical system (MEMS) transducer coupled to a bottom surface of the substrate;
a lid coupled to a top surface of the substrate, wherein the lid comprises an audio inlet into an inlet cavity encapsulated by the lid and the substrate, wherein the inlet cavity is connected to a cavity of the MEMS transducer via a first opening in the substrate; and
an attenuator lid coupled to a bottom surface of the substrate and enclosing the MEMS transducer, wherein:
the attenuator lid and the substrate encapsulate an attenuator cavity, and
the inlet cavity and the attenuator cavity are connected via a second opening in the substrate.

16. The microphone system of claim 15, wherein the cavity of the MEMS transducer comprises a region encapsulated by the substrate and the MEMS transducer.

17. The microphone system of claim 15, wherein the MEMS transducer comprises: a backplate and a diaphragm separated from the backplate by a width.

18. The microphone system of claim 15, wherein at least one of the audio inlet, the first opening, or the second opening are covered by an acoustic resistance element.

19. The microphone system of claim 15, further comprising an application specific integrated circuit (ASIC) configured to measure a change in capacitance of the MEMS transducer.

20. The microphone system of claim 15, wherein the substrate comprises a printed circuit board (PCB) electrically connected to the MEMS transducer via one or more contact pads on the substrate.
